(19) United States
(12) Patent Application Publication
(10) Pub. No.: US 2026/0343828 A1
(43) Pub. Date: Oct. 29, 2026

(54) DATA CENTER COOLING

(71) Applicant: Schlumberger Technology Corporation, Sugar Land, TX (US)

(72) Inventors: Andrew Clarke, Cambridge (GB); Mahdi Davoodi, Cambridge (GB)

(21) Appl. No.: 19/311,047

(22) Filed: Aug. 27, 2025

(30) Foreign Application Priority Data
Apr. 28, 2025 (GB) 2506418.9

(51) Int. Cl. H05K 7/20

(52) U.S. Cl. CPC H05K 7/2079; H05K 7/20754; H05K 7/20772; H05K 7/20836

(57) ABSTRACT

A data center cooling system has numerous heat input locations at which liquid coolant collects heat energy emitted from electronic components, a heat exchanger for discharging heat energy to another system, and pipework carrying coolant between the input locations and the discharging heat exchanger. The coolant liquid is a solution of a compound able to form worm-like micelles and the heat-input locations induce the micelles to cause elastic turbulence at those locations. The worm-like micelles also reduce drag in the pipework between the heat inputs and the heat exchanger.

### CROSS REFERENCE TO RELATED APPLICATIONS

This application claims priority to GB Patent Application No.: 2506418.9, which was tiled on Apr. 28, 2025, and is incorporated herein by reference in its entirety.

### FIELD

This disclosure relates to cooling electronic components and circuit boards carrying electronic components such as are used in large numbers in data centers.

### BACKGROUND

A data center typically contains numerous racks of computing equipment containing circuit boards on which there are electronic components which produce heat as they operate. It is conventional that a data center has a combination of systems for cooling these components during operation. One system may contain a circulating coolant liquid which is heated at multiple locations at or close to the racks where the heat is generated and then flows through pipework to a heat exchanger where the heat energy is discharged to another cooling system which carries the heat energy elsewhere, for example to the environment outside the building.

The coolant used in such system may be an aqueous solution, such as an aqueous solution containing 25% by weight of a glycol. The amount of coolant liquid in such a system may be large. A typical system may have heated solution arriving at the heat exchanger where it will be cooled at a rate of 10 cubic meters (about 2600 US gallons) per minute. A pipe of 35 cm (14 inch) diameter may be used to carry the fluid as it arrives at the heat exchanger. With such a flow rate and pipe size the flow of liquid is turbulent. Within the pipework, which may be lengthy, such turbulence is disadvantageous because it dissipates energy which has to be supplied by the pumping system. A known approach to mitigate this disadvantage is to add a drag reducing agent to the flowing liquid. Such an additive, which is usually a polymer reduces turbulence adjacent to the pipe wall and thereby reduces the required pumping power or increases the flow rate without requiring more pumping power.

### SUMMARY

This summary is provided to introduce concepts that will be further elaborated and described below in the detailed description. This summary is not intended to identify key or essential features of the claimed subject matter, nor is it intended to be used as an aid in limiting the scope of the claimed subject matter.

The present disclosure uses a substance able to form worm-like micelles as an additive which enables the circulating coolant liquid to be in a state of elastic turbulence in the locations where the coolant collects heat energy, thereby making the collection of heat energy more efficient, and which also acts as a drag reducing agent during turbulent flow along pipelines to and from a heat exchanger which discharges the heat energy to another cooling system. The worm-like micelles are believed to reduce turbulence at the periphery of the flow, adjacent to pipe walls and this reduction of drag can reduce the energy required for pumping.

In a first aspect, the present disclosure provides a data center cooling system comprising a plurality of heat input locations configured for collecting heat energy emitted from electronic components, a heat exchanger for discharging heat energy to another system, pipework configured for carrying heated coolant liquid from the heat input locations to the discharging heat exchanger, pipework configured for return flow of coolant liquid from the discharging heat exchanger to the heat input locations, and at least one pump for circulating the coolant liquid around the cooling system, wherein the coolant liquid is a solution of a compound able to form worm-like micelles and at least some of the heat input locations define one or more flow paths shaped to compel the flow of coolant liquid to make a succession of changes of direction of the coolant liquid flow in order to enable elastic turbulence to occur at those heat input locations.

A second aspect of the present disclosure provides a method of transferring heat energy arising within a data center, comprising pumping a coolant liquid from a plurality of heat input locations at which the coolant liquid collects heat energy emitted from electronic components through pipework to a heat exchanger for discharging heat energy to another system and through return pipework from the discharging heat exchanger to the heat input locations, wherein the coolant liquid is in a state of inertial turbulence during flow within at least part of the pipework connected to the discharging heat exchanger and the coolant is a solution containing a compound which forms worm-like micelles that reduce resistance to flow within that pipework, and wherein at least some of the heat-input locations define one or more paths of coolant flow shaped to compel the direction of flow to make a succession of changes of direction and the rates of coolant flow at some or all of the heat-input locations are such that the coolant flow is in a state of elastic turbulence at those locations.

The compound which is able to form worm-like micelles may have a molecular weight not greater than 1000 Daltons.

In some embodiments of this disclosure, the worm-like micelles are disrupted at or close to the inlet to the heat exchanger at which the heat energy is discharged. Then, in some embodiments, the worm-like micelles serve as drag reducing agents in pipelines for flow (in both directions) between the heat input locations and the heat exchanger where heat is discharged, while also providing elastic turbulence to enhance heat transfer at the heat input locations and with enhanced heat transfer in the heat exchanger where heat is discharged, because the worm-like micelles are disrupted as they enter that heat exchanger.

In some embodiments of this disclosure the coolant liquid also comprises suspended particles of a substance which is insoluble in the coolant liquid and which has a melting temperature which is above 25 °C but below an operating temperature limit of the electronic components. Inclusion of such a substance increases the amount of heat energy which can be carried by the circulating liquid.

### BRIEF DESCRIPTION OF THE DRAWINGS

FIG. 1 is a schematic cross section of a data center building.

FIG. 2 is a schematic cross section of a computing device on line Y-Y of FIG. 3.

FIG. 3 is a cross section on line X-X of FIG. 2.

FIG. 4 is a cross section of a hollow vessel for through flow of coolant liquid.

FIG. 5 is a cross section of the same hollow vessel on the line Z-Z of FIG. 4.

FIG. 6 is an enlarged cross-section in the same plane as FIG. 4.

FIG. 7 is a cross section, of another hollow vessel.

FIG. 8 is a schematic cross section of a data center building with different pumping to that in FIG. 1.

FIG. 9 is a cross section of a portion of pipework configured to cause extensional flow of liquid entering the heat exchanger.

FIG. 10 is a cross section of the same portion of pipework on the line J-J of FIG. 9.

FIG. 11 is a cross section on the lines K-K of FIGS. 9 and 10.

FIG. 12 is a cross section of a portion of pipework also configured to cause extensional flow of liquid entering the heat exchanger.

FIG. 13 is a schematic cross section of a data center building with different methods of collecting heat from electronic components.

FIG. 14 is a cross section of coolant bath and associated heat exchanger.

### DETAILED DESCRIPTION

This detailed description shows various embodiments of the present disclosure and possibilities which may be used. These are given as examples and do not limit this disclosure as defined by the claims. It should be appreciated that features or possibilities described in combination may, where it is practical to do so, be used separately. Also, features or possibilities described in any embodiment may be used in any other embodiment, in so far as it is possible to do so.

The present disclosure uses the phenomenon of elastic turbulence. It is of course well known that Newtonian liquids such as pure water can undergo either laminar flow or turbulent flow. Such turbulent flow may be referred to as inertial turbulence. Inertial turbulence within a pipe or other structure occurs at a higher speed of flow than laminar flow in the same pipe or structure. Conditions for laminar flow and inertial turbulent flow are often expressed by Reynolds number which is a ratio of inertial to viscous forces within a liquid. Reynolds number has no dimensions because it is a ratio. At Reynolds number above about 2000 there is inertial turbulent flow. At Reynolds number below about 1500, flow of a Newtonian liquid is laminar.

Elastic turbulence is different from inertial turbulence. It is a physical phenomenon discovered during the later part of the twentieth century. It has been observed at low flow speeds where Reynolds number is low and a Newtonian liquid would be in a state of laminar flow. Some early observations of elastic turbulence used the older term “elastic instability”. However, that term is more general and includes other forms of instability in flow. Literature documents relating to elastic turbulence include a detailed discussion by Steinberg in Annual Review of Fluid Mechanics, vol 53, pages 27-58 (2021).

Elastic turbulence occurs in solutions containing a solute which has a flexible structure. One category of material which is able to undergo elastic deformation and enable a solution to display elastic turbulence is a viscoelastic surfactant which forms worm-like micelles in solution. Such micelles have also been referred to as “rod-like”. Scientific literature concerning surfactants which form worm-like micelles, their properties and applications includes a review by Yang “Viscoelastic worm-like micelles and their applications” Current Opinion in Colloid & Interface Science vol 7 pages 276_281 (2002). Discussions of properties include Raghavan and Kaler “Highly Viscoelastic Worm-like Micellar Solutions Formed by Cationic Surfactants with Long Unsaturated Tails” Langmuir vol 17, pages 300-306 (2001) and Beaumont et al “Turbulent flows in highly elastic worm-like micelles” Soft Matter vol 9 page 735 (2013).

A number of viscoelastic surfactants which spontaneously form worm-like micelles in aqueous solution are set out in T. Saeki “Flow properties and heat transfer of drag reducing surfactant solutions” which is chapter 18 of “Developments in Heat Transfer” edited by D. M. A. D. S. Bernardes, published by InTechOpen, 2011. One possibility mentioned there is cetyl-trimethyl-ammonium chloride in a solution also containing sodium salicylate. Another possibility is stearyl-trimethyl-ammonium chloride which is effective in reducing drag at temperatures up to and above 100 °C. A suitable concentration of a viscoelastic surfactant to form worm-like micelles may be 10 gm/litre or less, possibly from 1 to 10 or 1 to 5 gm/litre. Such a compound may have a molecular weight not greater than 1000 Daltons.

Another category of material able to facilitate a solution to display elastic turbulence is a flexible long chain polymer. However, if a linear polymer molecule is broken, it is a covalent bond within the polymer chain which is broken and that breakage is not reversible, whereas the formation of worm-like micelles by a surfactant is the result of attractions between molecules, and in consequence if such micelles are broken up they can spontaneously reform.

When a solution contains a substance able to cause elastic turbulence, the phenomenon of elastic turbulence occurs if the solution is flowing at a sufficient flow velocity (which may be a low velocity and below velocities at which there is inertial turbulence) and the path of flow causes the streamlines of the flow to make a succession of changes of direction, thereby causing the direction of flow to curve. The changes in direction may be continuous curvature as in concentric or helical flow or may alternate between turning to the right and to the left. Consequently, one known possibility for a flow path which induces elastic turbulence is a serpentine channel. Another possibility is a flow path with obstructions which compel the streamlines of flow to change direction. Such obstructions may be manufactured and arranged in a pattern so as to compel the flow around the obstructions to change direction.

To summarize: the phenomenon of elastic turbulence of a liquid requires:
(i) a solute whose dissolved form has sufficient length to have elastic properties, enabling the liquid solution to display elastic turbulence,
(ii) a flow path for the liquid which compels a succession of changes in its direction of flow, and
(iii) pumping the liquid along the flow path at a sufficient velocity, but below velocities at which inertial turbulence occurs.

Worm-like micelles also have a further function in this disclosure. When a liquid solution containing an additive which enables the formation of such micelles is made to flow through a pipe (or some other structure) at a flow rate which is fast enough to create inertial turbulence, the worm-like micelles function as a drag reducing agent, altering the interaction between the flowing solution and the wall of the pipe. This can improve the flow rate along the pipe compared to the flow rate with the same pumping power but without the additive.

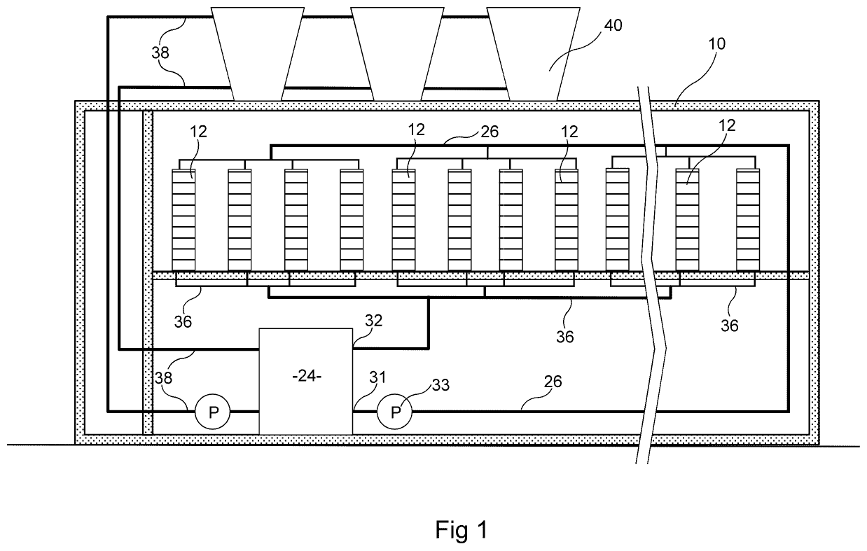

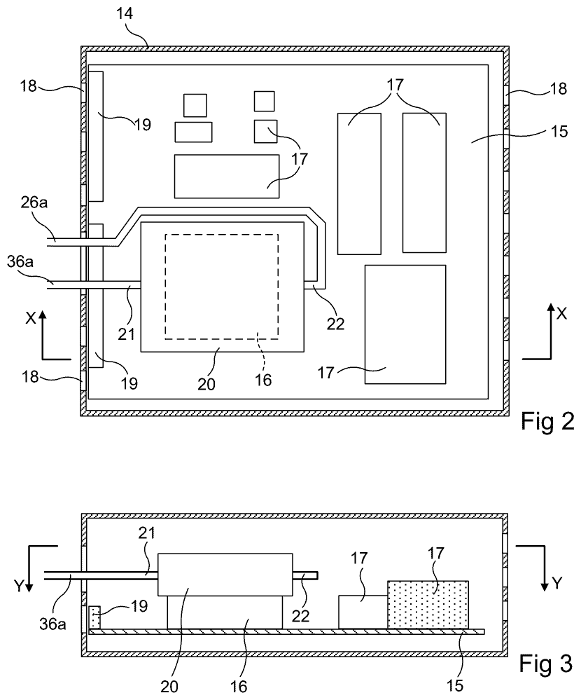

Embodiments of this disclosure will now be described by way of example. FIG. 1 is a diagrammatic representation of building 10 which is a data center. The building contains a large number of racks 12 each of which contains a number of computing devices such as servers. One such computing device is shown schematically by FIGS. 2 and 3. It has an outer case 14 inside which is a printed circuit board 15 to which various electronic components are soldered. The components may include a CPU 16 or one or more GPUs as well as other components 17. The case 14 has openings 18 at opposite ends to allow air to flow through and also to allow electrical connections to connector blocks 19.

During operation, the CPU 16 emits heat. Cooling of the CPU is provided by a so-called cold plate which comprises a hollow vessel 20 made of metal such as copper or aluminum and mounted in direct contact with the CPU 16 so as to allow heat emitted by the CPU to be conducted into the vessel 20. Coolant liquid is supplied to the vessel 20 at inlet 21 and leaves at outlet 22. Many or all of the numerous other computing devices in the racks 12 also have cold plates 20 in them, to collect heat emitted from CPUs, GPUs and other components which emit heat during operation. The internal features within a cold plate are further described below.

A cooling system connected to the numerous computing devices includes a large heat exchanger 24, one side of which has an inlet 31 with pump 33 close to it. The pump 33 is connected by a branching system of pipework 26 to the outlets 22 of the cold plates which are heat input locations of the cooling system. The outlet 32 of the heat exchanger 24 is connected to a similar branching system of pipework 36 for return flow to the cold plates. The large heat exchanger 24 transfers heat energy in the flow from the cold plates 20 to water flowing in another flow circuit 38 which carries the heat to cooling towers 40 on the roof of the data center 10.

The inlet 21 and outlet 22 of the vessel 20 of each cold plate have small diameter pipes 26a, 36a connected to them. These are part of the branching pipework systems 26 and 36. The inlet 31 and the outlet 32 of the heat exchanger 24 and the pipes connected to them are of large diameter. The branching systems of pipework 26, 36 may also include pipes of intermediate diameters. These branching systems may also include components other than pipes. For example, the system 36 which carries flow from the heat exchanger 24 to the heat input locations may include flow controlling valves and/or auxiliary pumps to control the proportions of flow in each of a number of pipes extending from a branch point.

The heat exchanger 24, the pipework systems 26, 36 and the vessels 20 of the cold plates are filled with a coolant liquid which may be an aqueous solution of a glycol. The pump 33 propels coolant flow around the circuit so that heated coolant from the outlets 22 of the cold plates is carried through the pipework system 26 to the pump 33 and the inlet 31 of the heat exchanger. Return flow of cooled liquid is carried from the outlet 32 of the heat exchanger through the pipework 36 to the inlets of the cold plates. In the larger diameter pipes of the pipework systems 26,36 and in particular in the pipes connected to the pump 33 and outlet 32 of the heat exchanger 24 the coolant travels at a sufficiently high flow rate that the flow is in a state of inertial turbulence, with a Reynolds number over 2000 (and possibly over 10,000).

Flow within the small pipes 26a, 36a connected to the inlet 21 and outlet 22 of a cold plate is at a lower flow rate and may be laminar flow at a Reynolds number below 1500. Flow within a cold plate may be even slower, corresponding to a Reynolds number of 1000 or less, because the cross section available for flow through the interior of the vessel 20 of the cold plate is greater than the cross section at the inlet and outlet of the cold plate.

The coolant liquid circulating from the cold plates to the heat exchanger 24 and back again to the cold plates 20 contains a small percentage of a viscoelastic surfactant able to form worm-like micelles. In the parts of the pipework systems 26, 36 where flow rate is high and the flow is in a state of inertial turbulence, these micelles modify the interaction between the coolant and the pipe walls and so enhance the rate of flow or enable use of a less powerful pump 33 than would be required in the absence of the worm-like micelles.

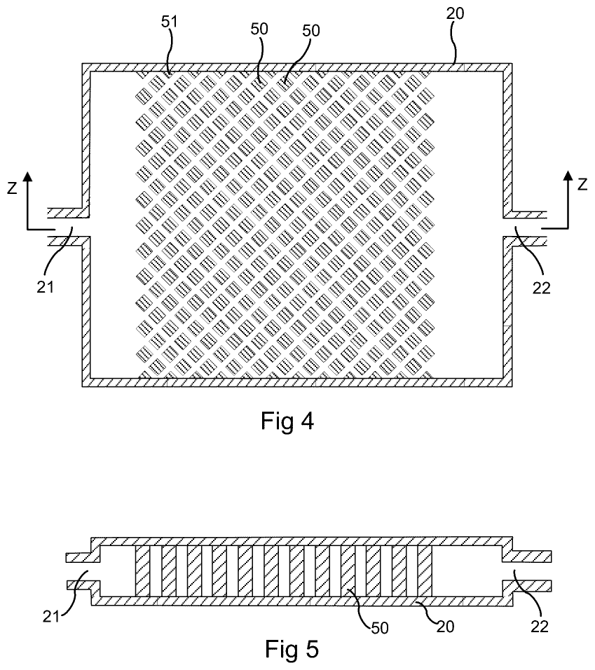

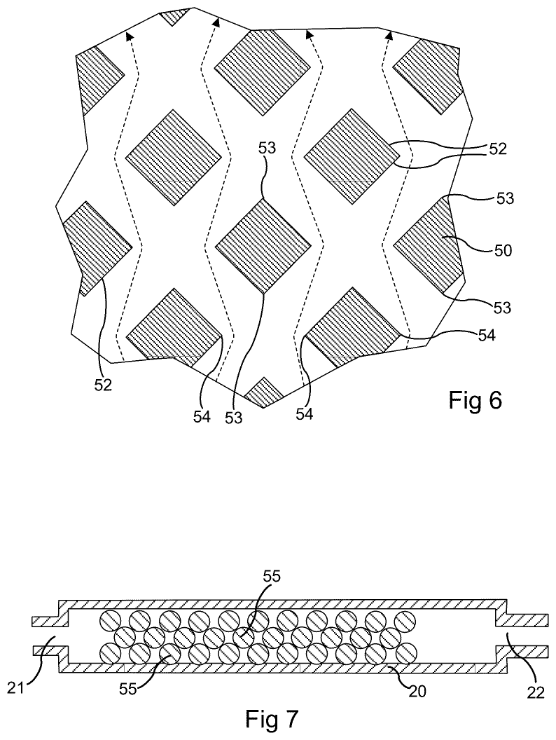

The cold plate 20 is configured to compel flow through its interior to make a succession of changes of direction in order to induce elastic turbulence within the cold plate. As shown by FIG. 5, an array of pillars 50 extends across the interior of the vessel 20 from its face which is in direct contact with the CPU 16 to the opposite face. As shown by FIG. 4 and the enlargement, which is FIG. 6, the pillars 50 have a square cross section with flat faces 52 meeting at corner edges 53 and 54. As shown in FIG. 4, the edges of the array are completed with pillars 51 which have a triangular cross section. Each pillar 50 is positioned so that the diagonal across the square cross section between corner edges 53 is aligned parallel to an imaginary line from the inlet 21 to the outlet 22. Thus the flat faces 52 of each pillar are inclined to the overall direction of flow. As shown by the enlarged view in FIG. 4, coolant liquid flows through the gaps between confronting edges 54 of adjacent pillars 50, but is then compelled to turn by another pillar. Thus the array of pillars 50 obstructs straight line flow of coolant, causing the streamlines of the flow indicated with broken lines in FIG. 4 to bend repeatedly.

The flow rate through the cold plate 20 is arranged to be sufficient that the worm-like micelles in the coolant liquid put that liquid in a state of elastic turbulence as it flows through the arrays of pillars. This has the effect of transferring heat energy from the casing surface 20 to the working fluid more rapidly than would be transmitted by conduction under conditions of laminar flow without elastic turbulence.

FIG. 7 shows an alternative internal structure for a cold plate. The interior of the plate contains a packing of spheres made of the same metal as the outer parts of the cold plate. The spheres are fixed in place by sintering. These spheres create tortuous paths for flow through the gaps between the spheres and so the flow is compelled to change direction repeatedly.

A flow rate which is sufficient to cause elastic turbulence can be determined experimentally using pressure gauges to monitor the drop in pressure between the inlet and outlet of a cold plate as the flow rate is slowly increased. As the flow rate increases from zero, the pressure drop will initially be directly proportional to the rate of flow. When elastic turbulence begins, the ratio of pressure drop to flow rate changes and a graph of pressure drop against flow rate will show a change in slope.

Although the worm-like micelles are beneficial in reducing drag in the large pipes connected to the heat exchanger 24 and pump 33, they would interfere with transfer of heat energy through the structure of the heat exchanger to the water in the other side of the heat exchanger which is connected to the pipes 38. In this embodiment the worm-like micelles are temporarily disrupted at or adjacent to the inlet 31 of the heat exchanger 24 by the pump 33 which applies high shear to the liquid while pumping it into the inlet 31 of the heat exchanger 24.

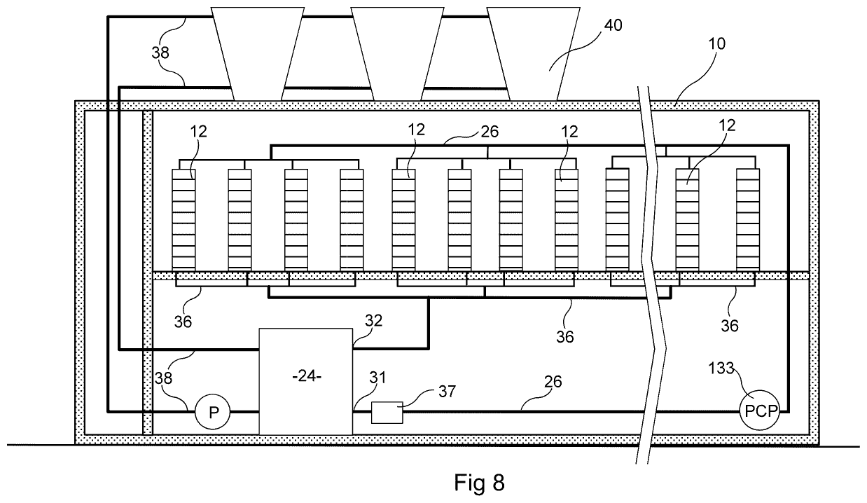

FIG. 8 shows a different arrangement for pumping liquid from the heat input locations to the heat exchanger 24. The pump 133 is a progressive cavity pump which will not apply strong shearing force to the liquid. This is located at a distance upstream of the inlet 31 to the heat exchanger 24 so that there is a long pipeline from the pump 133 to the heat exchanger inlet 31. The worm-like micelles reduce drag along this pipeline by modifying interaction between the flowing liquid and the pipe walls. It is believed that they reduce turbulence at the periphery of the flow. Adjacent to the inlet 31 to the heat exchanger 24 there is a structure 37 which forms part of the pipework system 26 and which compels the liquid flowing through it to undergo extensional flow, which disrupts the worm-like micelles.

Because the worm-like micelles are formed as a result of attractions between molecules, rather than covalent chemical bonds, these micelles are able to reform and resume their action of reducing turbulence and drag at the pipe walls, but this is not instantaneous and so for at least part of the flow through the heat exchanger 24, the inertial turbulence of the liquid will extend to the solid surfaces of the heat exchanger through which heat is discharged to another cooling system, thereby giving more efficient transfer of the heat energy and cooling of the flowing liquid.

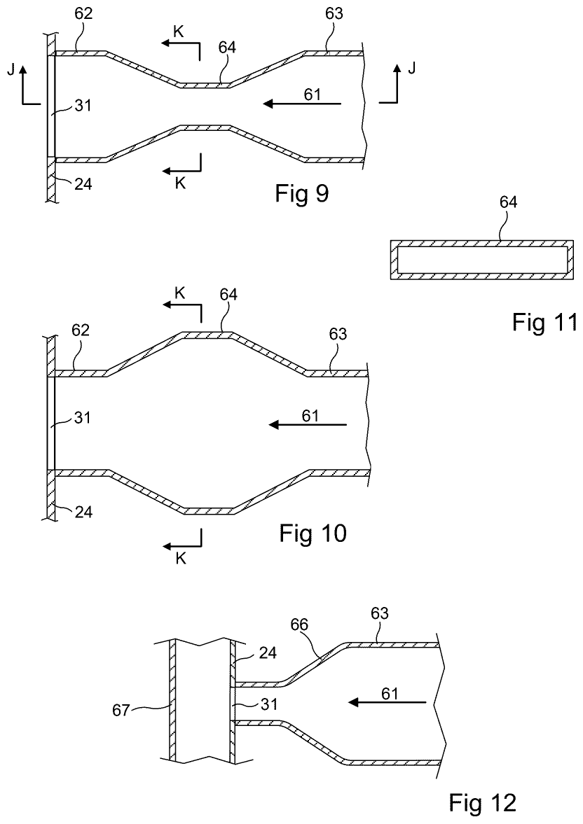

FIGS. 9 to 11 show one possible form for a structure 37 whose purpose is to compel fluid arriving at the inlet 31 to undergo extensional flow which disrupts the worm-like micelles. This structure is positioned close to the inlet 31 of the heat exchanger 24. The flow direction is indicated by arrow 61. The portions of the structure indicated as 62 and 63 are cylindrical and have the diameter of the pipe approaching the inlet 31. The portion 64 has a rectangular cross section shown by FIG. 11 and this has a cross sectional area for flow which is less than the cross sectional area of the cylindrical sections 62 and 63. This compels the incoming flow towards the heat exchanger to accelerate and therefore undergo extensional flow which disrupts the worm-like micelles just before the flow arrives at the inlet 31 of the heat exchanger 24.

It is desirable that the structure to cause extensional flow is located close to the inlet 31 of the heat exchanger. It may for instance be no more than 2 meters from the heat exchanger inlet 31, possibly no more than 1 meter from the inlet 31.

Another possibility for structure 37 to cause extensional flow is shown in FIG. 12. As the pipe approaches the inlet 31 of the heat exchanger 24 it includes a conical portion 66 which accelerates the flow and forms it into a jet. This jet is directed into the heat exchanger and strikes an internal wall within the heat exchanger, thereby creating further extensional flow which disrupts the worm-like micelles.

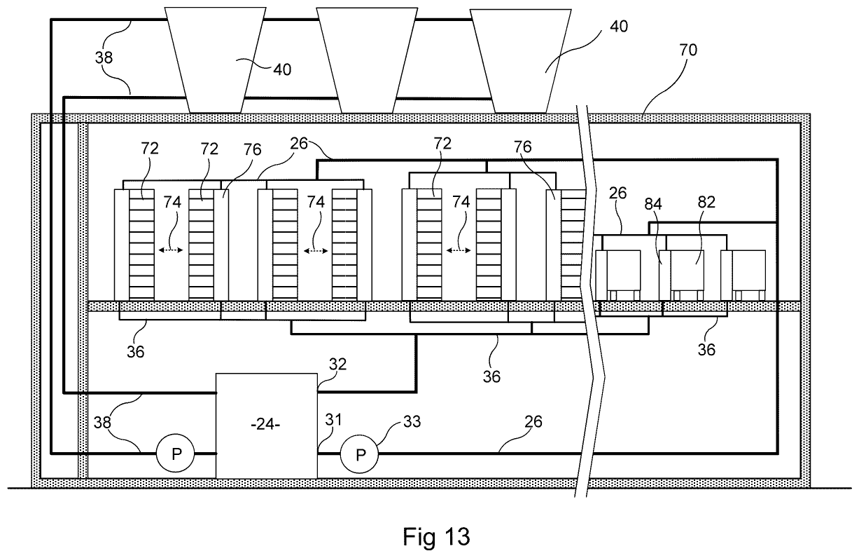

FIG. 13 is a schematic view of a data center which differs from that of FIG. 1 in that it uses other methods of collecting heat energy from electronic components which generate heat when they operate. In part of the building 70 there are racks 72 each of which contains a number of computing devices. These are similar to those shown in FIGS. 2 and 3 except that they do not include cold plates. They have an outer case 14 inside which there is a printed circuit board to which electronic components 16, 17 are soldered.

The racks 72 are arranged in pairs facing each other. To cool the electronic components 16, 17 air is blown into the aisle between each pair of racks 72, for the air to flow into the computing devices in the racks as indicated at 74. At the other side of each rack 72 there is a so-called rear-door heat exchanger 76 which transfers heat energy from the air to a flow of coolant liquid. It is also possible to locate heat exchangers which transfer heat from the airflow to the coolant liquid at other positions, such as above the racks 62.

The data center has a cooling system which has a heat exchanger 24 and branching pipework systems 26, 36 as described above. These systems of pipework are connected to the rear door heat exchangers 76 so that heat energy carried by the air flow is transferred to the coolant liquid passing through the heat exchangers 76.

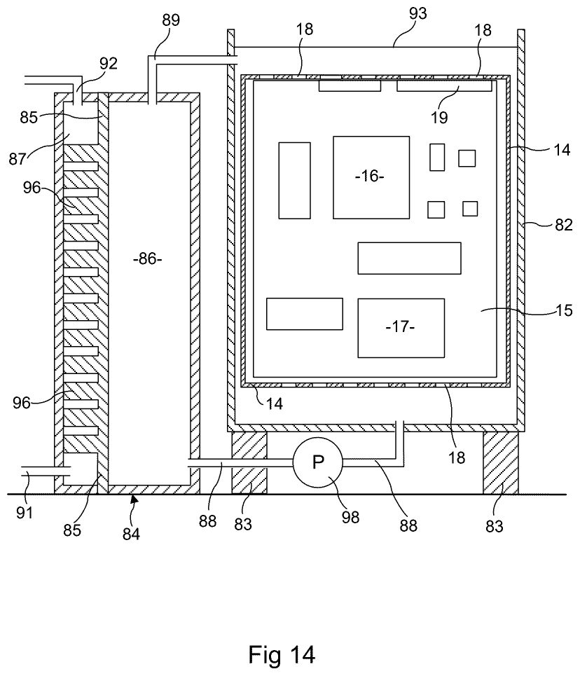

In another part of the building 70, computing devices are cooled by immersion in baths 82 of a non-conductive liquid referred to as dielectric fluid. The baths 82 are indicated in FIG. 13 and shown in more detail in FIG. 14. Alongside the bath 82 there is a heat exchanger 84 with a divider 85 between its two chambers. The chamber 86 is connected to the bath 82 by pipes 88, 89 with a pump 98 to circulate dielectric fluid from the bath 82 through the chamber 86. The surface of the dielectric fluid in the bath is indicated at 93.

The other chamber of the heat exchanger 84, which is shown to the left of the divider 85 has an inlet 91 connected to the pipework system 36 and an outlet 82 connected to the pipework system 26 and so coolant circulated by the pump 33 flows through this chamber of the heat exchanger 84 to collect heat energy from the dielectric fluid.

The divider 85 is made of a metal with good thermal conductivity, such as copper or aluminum, and it is integral with an array of pillars 96 of square cross section arranged similarly to the pillars 50 in FIGS. 4 and 6. Consequently, liquid flowing through the chamber 87 is compelled to make a succession of changes of direction. As already mentioned, the coolant liquid contains a viscoelastic surfactant which forms worm-like micelles. The flow rate through the chamber is made sufficient that the coolant liquid will be in a state of elastic turbulence, which improves heat transfer from the divider 85 and pillars 96 to the flowing coolant.

In some embodiments of this disclosure, the liquid which circulates through the pipework 26, 36 and the heat exchanger 24 is an emulsion or suspension in which the disperse phase is able to melt and to freeze at temperatures which are above the temperature of cooled liquid flowing out of the heat exchanger 24 but below a maximum operating temperature for the electronic components which are being cooled by the circulating liquid. This will increase the heat carrying capacity of the circulating coolant liquid because melting of the disperse phase will require the latent heat of fusion of that phase in addition to heat to raise the temperature of the liquid.

As an illustration of this, if a circulating liquid is water and a unit mass of water with specific heat capacity cₚ^{water} is heated from temperature T₁ which is 25 °C to temperature T₂ which is 40 °C the enthalpy change is

$$Δ {E}^{water} = {c}_{p}^{water} ( {T}_{2} - {T}_{1} )$$

A hypothetical circulating liquid is an emulsion with a continuous phase which is water and a disperse phase which is nonadecane melting to an oil at 32 °C. If unit mass of an emulsion containing proportion φ of the hydrocarbon is heated over the same temperature range, and the melting point of the hydrocarbon is between T1 and T2, the enthalpy change is

$$Δ {E}^{pcm} = ϕ ( {L}^{oil} + {c}_{p}^{oil} ( {T}_{2} - {T}_{1} ) ) + ( 1 - ϕ ) {c}_{p}^{water} ( {T}_{2} - {T}_{1} )$$

where L^{oil} is the latent heat of fusion of the hydrocarbon and for simplicity it is assumed that the specific heat of the hydrocarbon is the same for its frozen and liquid forms. In the case of an emulsion containing 30 vol % of nonadecane as the disperse phase in water as continuous phase, and with a temperature rise of 15° between T₁=25 °C and T₂=40 °C spanning the 32 °C melting temperature of the nonadecane, the calculated enthalpy change of the emulsion is approximately twice that of water alone.

Various embodiments of this disclosure have been set out above. These are intended to assist understanding of this disclosure, but not to limit it in any way. It should be appreciated that any features or possibilities described in combination may, where it is practical to do so, be used individually. Also, features or possibilities mentioned in the following claims or described in any embodiment may be used in any other embodiment, in so far as it is practical to do so and where two or more of the following claims are dependent on the same preceding claim, the reader should understand that the present disclosure includes any possible combination of any two or more or all of those dependent claims with each other and also with that preceding claim.

1. A data center cooling system comprising:
a plurality of heat input locations at which coolant liquid collects heat energy emitted from electronic components;
a heat exchanger for discharging heat energy to another system;
pipework configured for carrying heated coolant from the input locations to the discharging heat exchanger;
pipework configured for return flow of coolant from the discharging heat exchanger to the said locations; and
at least one pump for circulating the coolant liquid around the system, wherein the coolant liquid is a solution of a compound able to form worm-like micelles and the heat-input locations define one or more paths of coolant flow shaped to compel a direction of flow to make a succession of changes of direction.

2. The system of claim 1, wherein the compound has a molecular weight not greater than 1000 Daltons.

3. The system of claim 1, wherein the coolant liquid comprises suspended particles of a substance which is insoluble in the coolant liquid and which has a melting temperature which is above 25 °C and below an operating temperature limit of the electronic components.

4. The system of claim 3, wherein the suspended particles have a melting temperature in a range from 30 °C to 60 °C.

5. The system of claim 3, wherein the coolant liquid is an aqueous solution and the disperse phase is a hydrocarbon.

6. The system of claim 1, wherein at each of a plurality of said heat input locations the system comprises a vessel in thermal contact with one or more heat emitting electronic components, the vessel having an internal chamber for through flow of coolant liquid, wherein the internal chamber comprises an array of obstructions configured so that liquid flow is repeatedly compelled to change direction and straight line flow through the internal chamber is not possible.

7. The system of claim 1, wherein at each of a plurality of said heat input locations the system comprises a local heat exchanger configured so that the coolant liquid flowing therethrough receives heat energy from air heated by heat-emitting electronic components or from a separate coolant liquid heated by heat-emitting electronic components.

8. The system of claim 1, wherein the pipework carrying coolant flow to the discharging heat exchanger is configured, adjacent to the inlet of the discharging heat exchanger, to compel the coolant to undergo extensional flow.

9. The system of claim 8, wherein the pipework adjacent to the inlet of the discharging heat exchanger is shaped to reduce a cross-sectional area available for flow and thereby compel the flow to accelerate.

10. The system of claim 8, wherein the pipework adjacent to the inlet of the discharging heat exchanger is shaped to form the flow of coolant into a jet directed at a fixed surface confronting the jet.

11. A method of transferring heat within a data center, comprising:
pumping a coolant liquid from a plurality of heat input locations at which the coolant liquid collects heat energy emitted from electronic components, through pipework to a heat exchanger for discharging heat energy to another system and return pipework from the discharging heat exchanger to the heat input locations, wherein the coolant liquid is in a state of inertial turbulence during flow within at least part of the pipework connected to the discharging heat exchanger and the coolant is a solution comprising a compound which forms worm-like micelles that reduce resistance to flow within the pipework, the heat-input locations define one or more paths of coolant flow shaped to compel the direction of flow to make a succession of changes of direction and the rates of coolant flow at the heat-input locations are such that the coolant flow is in a state of elastic turbulence.

12. The method of claim 11, wherein the compound has a molecular weight not greater than 1000 Daltons.

13. The method of claim 11, wherein the coolant liquid comprises suspended particles of a substance which is insoluble in the coolant liquid and which has a melting temperature which is above 25 °C and below an operating temperature limit of the electronic components.

14. The method of claim 13, wherein the suspended particles have a melting temperature in a range from 30 °C to 60 °C.

15. The method of claim 11, wherein the coolant liquid is an aqueous solution and the disperse phase is a hydrocarbon.

16. The method of claim 13, wherein at each of a plurality of said heat input locations the coolant flows through a hollow vessel in thermal contact with one or more heat-emitting electronic components, and obstructions within the hollow vessel interior block straight line flow through the interior and compel the coolant liquid flow to change direction repeatedly, thereby inducing elastic turbulence.

17. The method of claim 11, wherein at each of a plurality of said heat input locations coolant liquid flows through a local heat exchanger wherein the coolant liquid receives heat energy from air heated by heat-emitting electronic components or from a separate coolant liquid heated by heat-emitting electronic components.

18. The method of claim 11, wherein adjacent to the inlet of the discharging heat exchanger the pipework carrying coolant flow compels the coolant to undergo extensional flow.

19. The method of claim 18, wherein the pipework adjacent to the inlet of the discharging heat exchanger is shaped to reduce a cross-sectional area available for flow and thereby compel the flow to accelerate.

20. The method of claim 18, wherein the pipework adjacent to the inlet of the discharging heat exchanger is shaped to form the flow into a jet directed at a confronting fixed surface.
